(19) United States
(12) Patent Application Publication
(10) Pub. No.: US 2002/0114417 A1
(43) Pub. Date: Aug. 22, 2002

(54) Model for charge pump phase-locked loop

(76) Inventor: Stephen J. McDonagh, Dublin (IE)

Correspondence Address: Robert B. O'Rourke, BLAKELY, SOKOLOFF, TAYLOR & ZAFMAN LLP, Seventh Floor, 12400 Wilshire Boulevard, Los Angeles, CA, 90025-1026, US

(21) Appl. No.: 09/733,443

(22) Filed: Dec. 7, 2000

Related U.S. Application Data
(60) Provisional application No. 60/239,469, filed on Oct. 10, 2000.

(51) Int. Cl. H03L 7/06; H03D 3/24

(52) U.S. Cl. 375/376; 327/157

(57) ABSTRACT

A method and apparatus that represents a charge pump output signal as a superposition of current steps that step in opposite directions at different times.

CLAIM OF PRIORITY

This application hereby claims the benefit of a U.S. Provisional Application entitled “An Event-Driven Simulator Core For Charge-Pump Phase-Locked Loops” and filed on Dec. 7, 1999. A petition has been filed to ensure that the Dec. 7, 1999 filing date is granted. No application number has been provided.

### FIELD OF THE INVENTION

The field of invention relates generally to circuit modeling and; more specifically, to modeling a phase lock loop having a charge pump.

### BACKGROUND

FIG. 1 illustrates the block diagram of a typical charge pump phase locked loop 100 (CP-PLL), which may also be referred to as a phase lock loop or phase locked loop (PLL). The Voltage-Controlled Oscillator 101 (VCO) generates a clock (CLK or Clk) where the frequency is set by an input voltage. This voltage is controlled by a feedback loop which aligns the VCO clock to the input clock. The input clock may also be referred to as a reference clock (REF or Ref). This feedback loop consists of a phase/frequency detector (PFD) 102, charge-pump 103 and filter 104.

### Phase/Frequency Detector

The phase/frequency detector 102 monitors the phase difference between two clocks. A PFD is a sequential state- machine that changes state on clock transitions. FIG. 2 illustrates the state-diagram 200 of PFD 102 of FIG. 1. The PFD outputs (UP, DOWN) indicate which clock (REF or CLK) is leading/lagging and the width of these outputs indicate the phase difference between the two clocks.

### Charge-Pump

Referring back to FIG. 1, the charge-pump 103 (CP) sources or sinks current depending on the control inputs, UP and DOWN. This block is used to charge/discharge a loop filter 104.

### Loop Filter

The loop filter 104 affectively integrates current pulses provided by the charge pump 103. The loop filter 104 may consist of a series capacitor-resistor (Rz & Cs) in parallel with another smaller capacitor (Cp) as seen in FIG. 1. The series capacitor-resistor is used to stabilize the PLL. The smaller capacitor is used to smooth out any high frequency jumps across the resistor due to mismatch in the circuitry. Other loop filter designs may be used.

### Voltage Controlled Oscillator

The voltage controlled oscillator 101 (VCO) is used to generate a clock (CLK). Referring to FIG. 3, the VCO input voltage 301 (also referred to as a control voltage) sets a current internal to the VCO which is used to charge/discharge a capacitor (not shown) between two thresholds. When the capacitor voltage 302 hits a threshold, the current polarity is reversed and the capacitor is discharged towards the other threshold. This repeating process generates the output clock (CLK) 303. The higher the input voltage, the faster the timing capacitor is charged/discharged by the current. This results in a higher output clock rate.

### PLL Feedback Operation

Referring to FIG. 1, the phase detector 102 and charge-pump 103 help generate a current pulse which is equal to the time difference between the input (REF) and VCO clock (CLK). This current pulse is used to charge or discharge the filter 104. The polarity of the current pulse is typically designed such that the filter voltage will be decreased if the VCO clock (CLK) leads the input clock (REF) and will be increased if the VCO clock (CLK) lags the input clock (REF). This filter voltage is then used to control the VCO 101. This will create the necessary feedback to align both clocks. The loop will settle when the phase difference between the input and VCO clock is zero (i.e. the loop is phase-locked).

### Simulation of PLL

The design goal of a PLL is to generate a clock (CLK) which is exactly aligned to the input clock (REF). For this reason, PLLs are commonly used in applications which require clock-skew elimination, clock generation and clock/data recovery. PLLs are generally implemented as mixed-mode and non-linear feedback control systems. Typically, they exhibit a low system bandwidth while the internal circuitry operates at a much higher frequency.

This results in long run-times for simulation tools (such as SPICE) when evaluating PLL transient behavior. A simulation tool must adjust the time-step control to address the short time constants of the PLL's internal operation. However, the time scale of interest (e.g. the lock-in time) will be much longer due to this low system bandwidth.

Behavioral modeling and simulation reduce the run-time for PLL transient simulation (which should result in a shorter design time). There are many techniques and tools available which can be used to model and simulate PLLs. However many of these tools introduce approximations to balance the speed/accuracy trade-off. Approximations including the linearization of block behavior and the type of integration methods used will introduce errors and numerical noise into the transient response.

### SUMMARY OF INVENTION

A method and apparatus that represents a charge pump output signal as a superposition of current steps that step in opposite directions at different times.

### BRIEF DESCRIPTION OF THE DRAWINGS

The present invention is illustrated by way of example, and not limitation, in the Figures of the accompanying drawings in which:

FIG. 1 shows a charge pump phase locked loop (CP-PLL);

FIG. 2 shows a state diagram for a phase detector;

FIG. 3 demonstrates voltage controlled oscillator (VCO) operation;

FIG. 4 shows a model for a charge pump and a filter;

FIG. 5 shows a mathematical representation of a VCO;

FIG. 6 demonstrates the operation of a PLL;

FIG. 7 demonstrates a methodology for a model of a PLL;

FIG. 8 shows an example of a filter voltage that may be produced with the PLL model shown in FIG. 7;

FIG. 9 shows an example of a VCO output clock period that may be produced with the PLL model shown in FIG. 7;

FIG. 10 shows an example of a first jitter transfer function that may be produced with the PLL model shown in FIG. 7;

FIG. 11 shows an example of a second jitter transfer function that may be produced with the PLL model shown in FIG. 7;

FIG. 12 shows an example of a VCO transfer function that may be produced with the PLL model shown in FIG. 7.

### DETAILED DESCRIPTION

### 1.0 Mathematical Description of CP-PLL

The CP-PLL can be modeled by deriving mathematical representations/equations

### for the behavior of each individual block and combining them in an algorithm to describe the PLL feedback operation.

### Phase Detector

All reference clocks are known during the simulation run- time. When the VCO clock edges are calculated, an ‘if’ statement performs the phase detector function. This will indicate if the VCO clock is leading or lagging and therefore the polarity of the correction pulse.

### Charge-Pump

The output of the charge pump is a stream of current pulses. This can be modeled as the summation 402 of unit steps 401a, 401b of alternating polarity. That is, the superposition of current steps that step in opposite directions at different times. This is illustrated on the left-hand side of FIG. 4. This unit steps are time-shifted to the points where the VCO & input clock edges occur. The polarity of the pulses is dictated by the phase detector.

### Filter

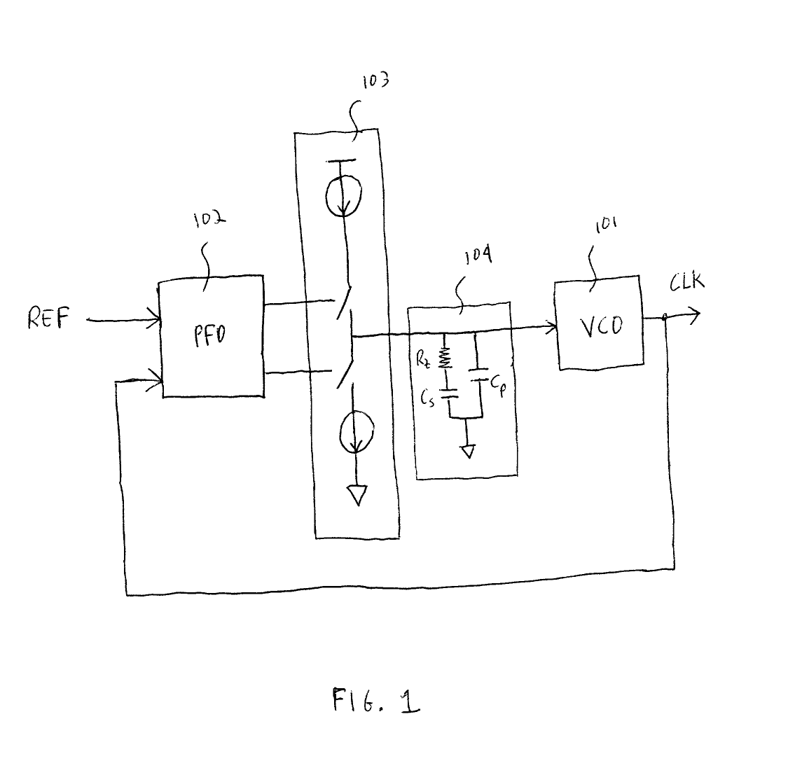

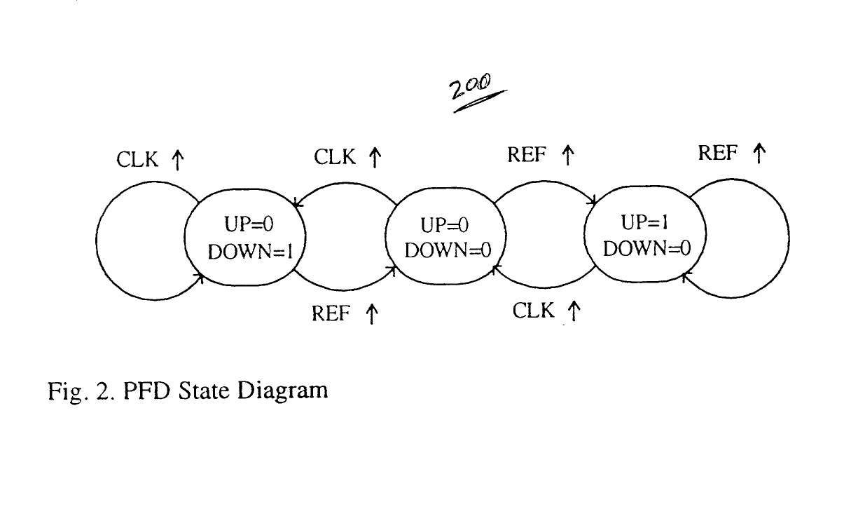

The filter is modeled by an equation which describes the time response of the filter to a unit step response. These step responses 403a, 403b are shifted in time (to where the VCO and input clock edges occur), multiplied by the correct polarity and added to construct the filter voltage response 404. This is illustrated on the right-hand side of FIG. 4. The step response of the filter shown in FIG. 1 to a step impulse can be found through the Laplace transform.

$${V}_{step} ( t ) = \frac{{1}_{cp}}{{C}_{s} + {C}_{p}} \cdot ( t + \frac{{R}_{z} \cdot {C}_{s}^{2}}{{C}_{s} + {C}_{p}} \cdot ( 1 - {ⅇ}^{- ( t ( \frac{{C}_{s} + {C}_{p}}{{R}_{z} \cdot {C}_{s} \cdot {C}_{p}} ) )} ) ) \qquad Eqn . 1$$

The filter voltage at time t can be found by adding together all the previous step responses.

$${V}_{filt}^{( t )} = {V}_{0} + {\sum }_{k = 1}^{N} {P}_{k} \cdot {V}_{step} ( t - {t}_{k} ) \qquad Eqn . 2$$

Where Pₖ and tₖ consist of the polarities and time-shifts of the k^{th} unit step respectively and N is the number of unit steps. V₀ is the initial voltage on the filter.

### Voltage Controlled Oscillator

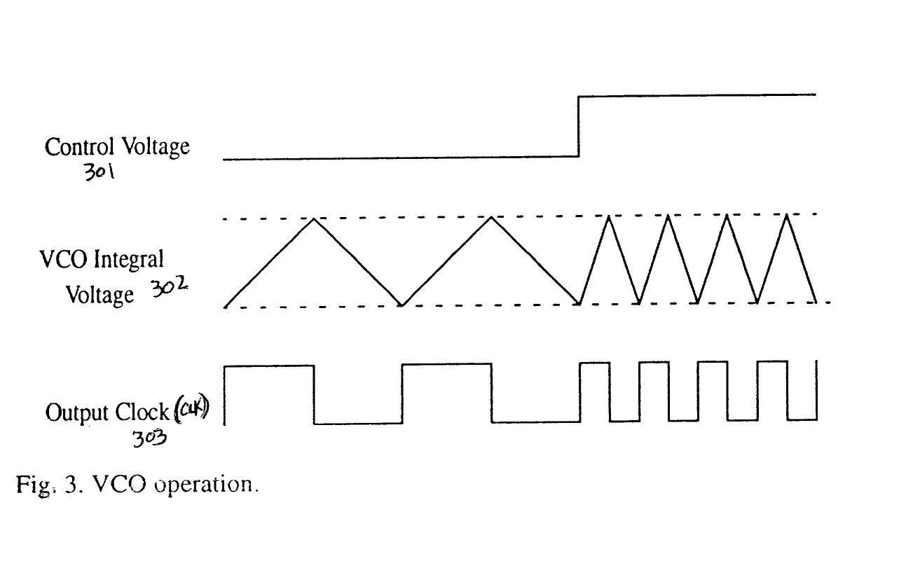

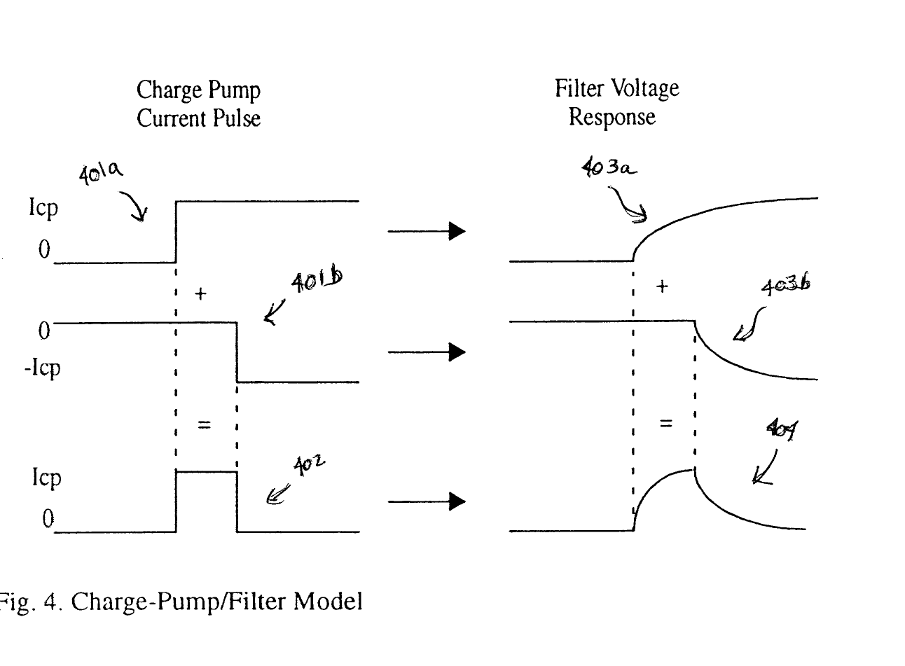

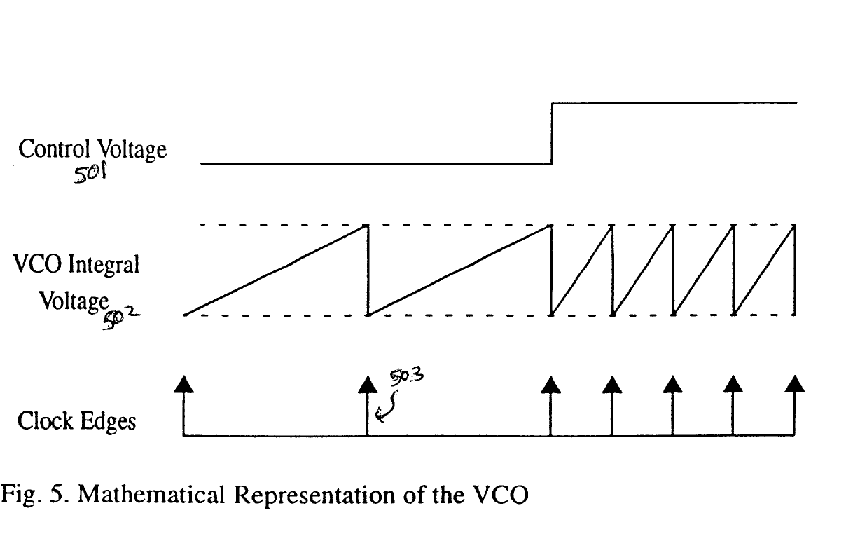

In an embodiment, the VCO may be modeled as an ideal relaxation oscillator. FIG. 5 illustrates the mathematical representation of such a VCO. The input control voltage 501 is integrated 502 and compared to a reference voltage. The next VCO edge (e.g., edge 503) occurs when this integral equals the reference voltage. The integral is set to zero and the process is repeated. This mathematical representation may look different to the VCO illustrated in FIG. 3. However, in this embodiment, only the location of the rising edges are of importance to the phase-detector and so the calculations are simplified. The VCO integral voltage can be defined as

$${V}_{VCO} ( t ) = {m}_{0} \cdot ( t - {t}_{x} ) + {k}_{i} \cdot {\int }_{{t}_{x}}^{t} {V}_{filt} ( t ) ⅆ t \qquad Eqn . 3$$

where m₀ is the slope associated with the free-running frequency of the VCO, Kᵢ is the integration constant associated with the VCO gain and tₓ is the last VCO switching time. The next VCO switching point, t, is found by solving the equation

$${V}_{VCO} ( t ) = a = {m}_{0} ( t - {t}_{x} ) + {k}_{i} \cdot {\int }_{{t}_{x}}^{t} {V}_{filt} ( t ) ⅆ t \qquad Eqn . 4$$

where a is the peak-to-peak threshold of the VCO. If the VCO gain K₀ is denoted as a fractional change of the VCO free-running frequency per unit (volt) of input, then

Kᵢ =K₀ ·m₀ Eqn.5

and

a=m_{0 ·}T₀ Eqn. 6

where T₀ is the VCO free-running period. Combining equations (4),(5) and (6) gives

$${T}_{0} = t - {t}_{x} + {K}_{0} \cdot {\int }_{{t}_{x}}^{t} {V}_{filt} ( t ) ⅆ t \qquad Eqn . 7$$

The solution to this equation, t, is the next VCO switching point (i.e., edge). In an embodiment, a numerical method such as the Newton-Raphson method is used to solve this equation.

### PLL Feedback Operation

The locations of the input clock edges are always known so the task for this model is to determine the location of the next VCO clock edge. If the initial conditions of the PLL are known it is possible to determine the next VCO switching point by solving equation (7).

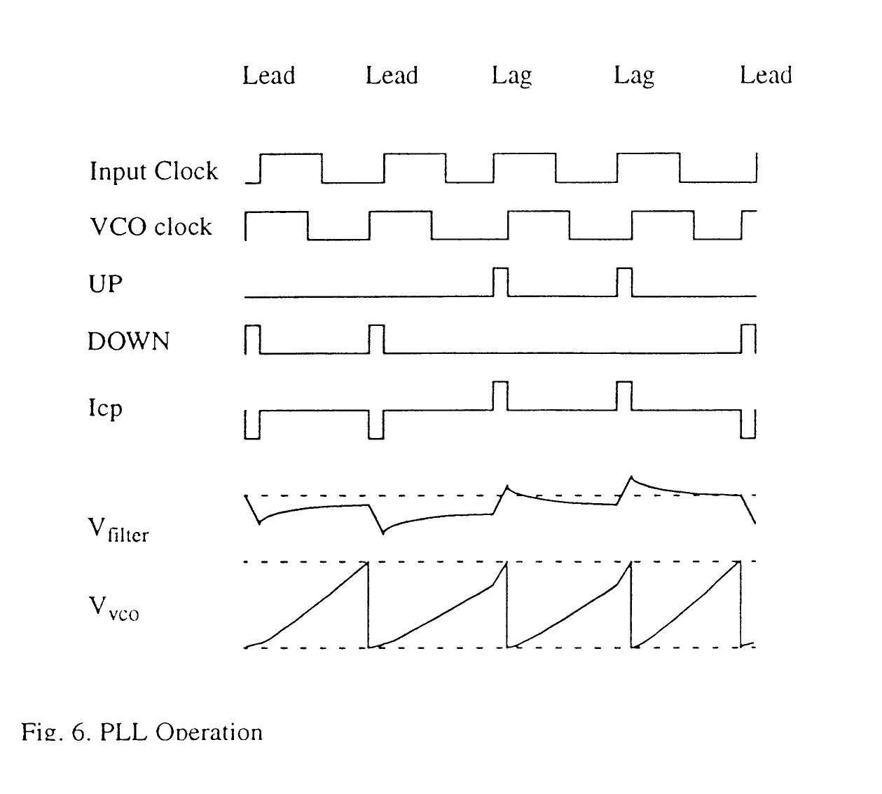

However, the PLL feedback operation complicates things. FIG. 6 illustrates the behavior of a CP-PLL which can be analyzed in terms of whether the VCO clock is leading or lagging the input clock at successive comparison instants. It can be seen that if the VCO is lagging the input clock, an UP pulse is initiated by the input clock. This pulse will act to increase the filter voltage which will cause the VCO to switch at an earlier instant. Therefore, the next VCO switching point must be re-evaluated to include an extra unit step due to the input clock. If the VCO clock occurs before the next input clock, the next case is LEAD and the time point is valid.

### 2.0 PLL Simulation

To summarize the previous section:

1. The filter voltage can be determined by adding the unit step responses due to all previous input and VCO edges and is described by equation (2).

2. The VCO switching point is determined by integrating the filter voltage and equating it to a reference level. This time point can be found by solving equation (7).

3. If the VCO is lagging the input clock, the effect of the input clock initiating an unit step on the filter voltage must be taken into account.

The locations and polarities of the input and VCO clock edges are then added to the previous unit step time points and the process is repeated.

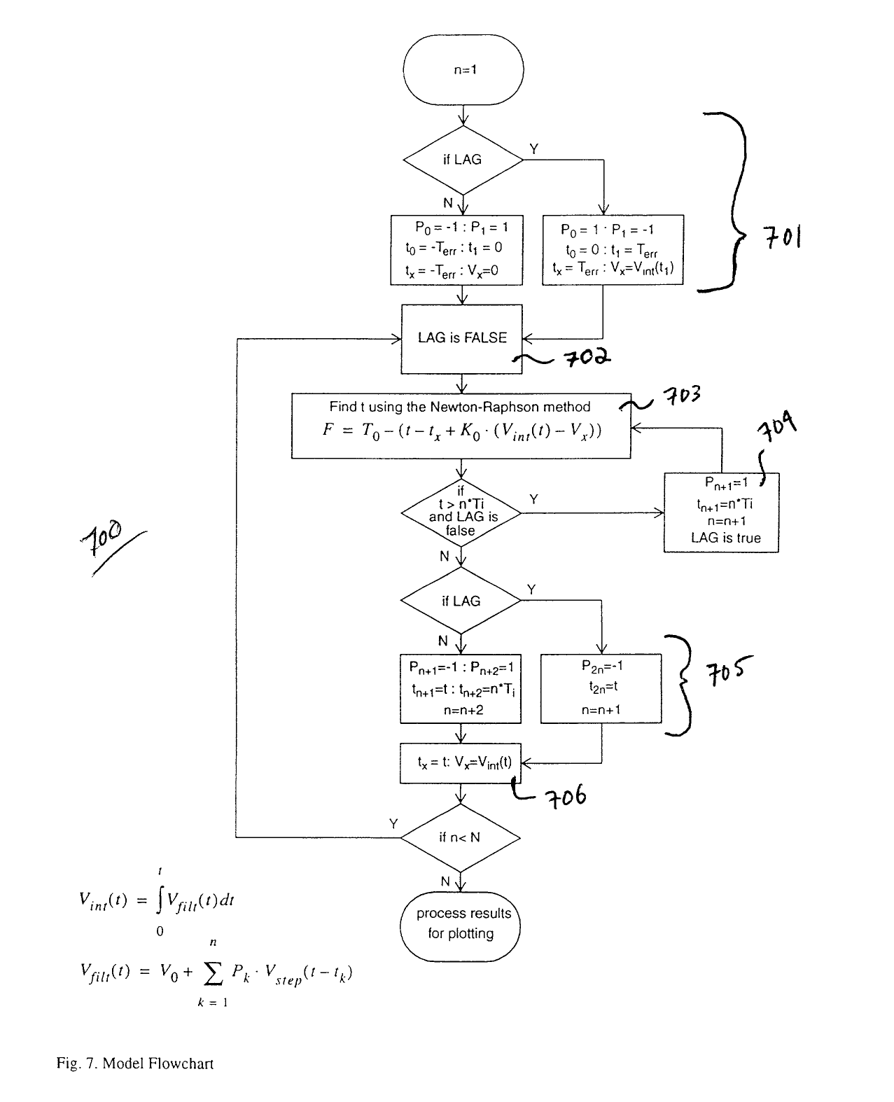

FIG. 7 illustrates a detailed flow chart 700 of an embodiment of the PLL simulation method. The inputs to the algorithm are the location of the input clock edges, the first VCO clock edge and the filter voltage. In response to these inputs the PLL simulation will output the VCO switching times.

The filter voltage can be re-constructed by using these time values and adding the filter unit step responses all shifted by the appropriate time with the correct polarity. The phase error is just the difference in time between the input reference edges and the VCO switching times.

With respect to the simulation method of FIG. 7, the initial conditions may be provided. Tₑᵣᵣ for the initial phase error and V₀ for the initial filter voltage. The variables of the algorithm include: 1) Pₙ which is the polarity of the n^{th} unit step; 2) tₙ which is the location of the n^{th} unit step; 3) tₓ which is the last VCO switching time; 4) Vₓ which is the filter integral at tₓ; and 5) LAG which is true if the VCO clock edge occurs after the next input clock edge.

After starting the simulation the variable arrays are initialized 701 depending on whether the first case is LEAD or LAG. Then, the next case is assumed to be LEAD 702. The next VCO switching point is then found 703. If the VCO clock edge occurs after the input clock edge, the next case is LAG. As such, the variable arrays are updated and the VCO switching point is recalculated 704. Variable arrays are then updated 705 depending on whether the case is LEAD or LAG. The variables that contain the last VCO switching point and the last VCO integral voltage are then updated 706. The next VCO switching point is then calculated if the simulation is not finished.

### 3.0 Model Performance

If the responses of the filter are added at each bit interval then the simulation time of the algorithm (FIG. 7) will grow by N! (where N=the number of bit intervals simulated). However, if the equations are expanded out and re-arranged, N^{th}-order simulation time is achieved.

Care should also be taken in how the exponential terms are stored as the terms can become quite large and cause numerical overflow on the computing machine.

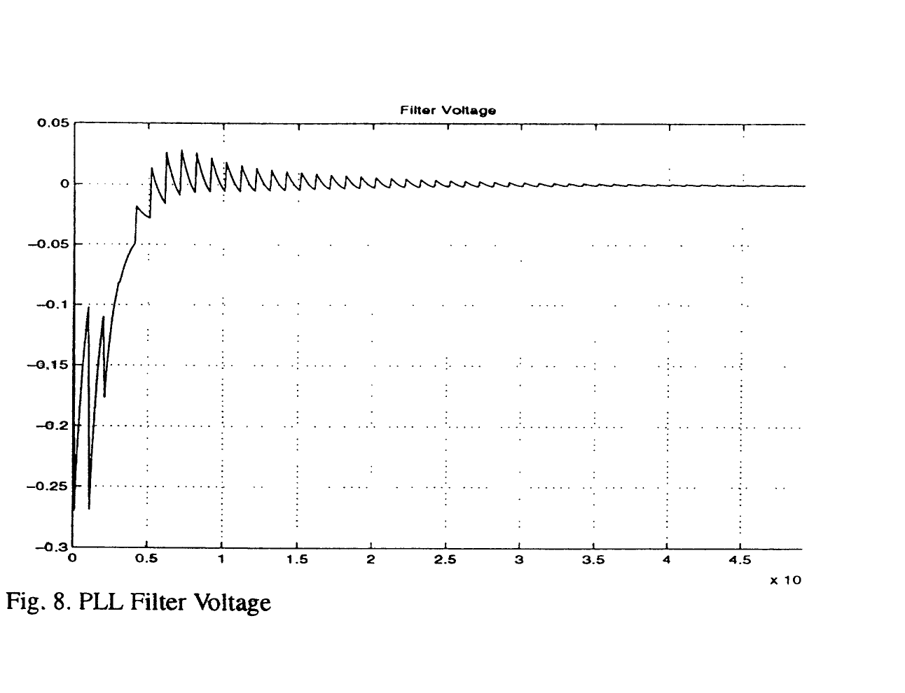

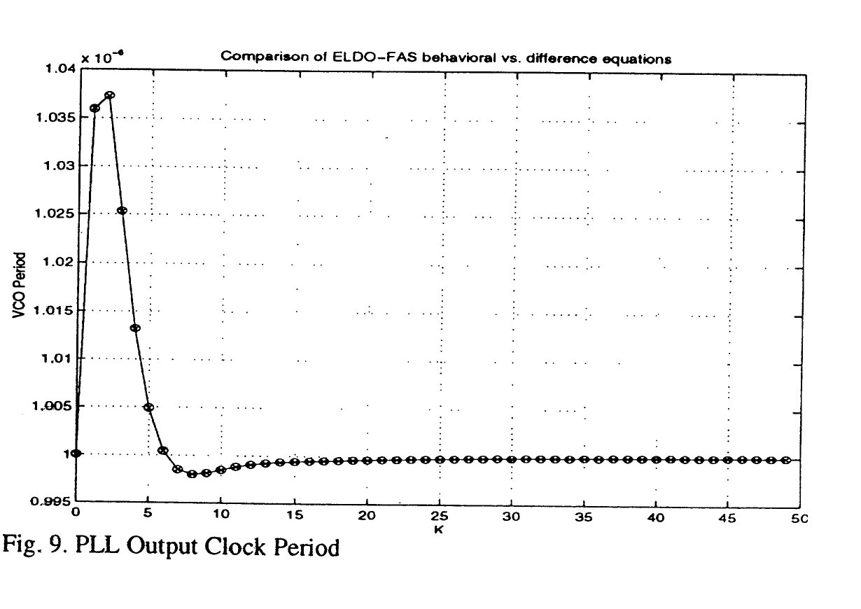

This model was compared against a behavioral model and a full transistor level PLL using the ELDO circuit simulator. All simulations were run on an ULTRA 5 machine. The filter voltage and VCO clock period are plotted in FIGS. 8 and 9. The full transistor level simulation took 3 days, the behavioral 2 hours and the PLL model 4 seconds.

### 4.0 Model Application

The model may be used to extract the frequency and transient responses of a PLL. It can also be used in an optimization routine and can include error sources such as jitter, noise and leakage which interfere with normal PLL operation.

### Frequency Analysis

The input clock edges are always known during the simulation and so the edges can be shifted during the run. Therefore the model can be used to plot the frequency response of the PLL.

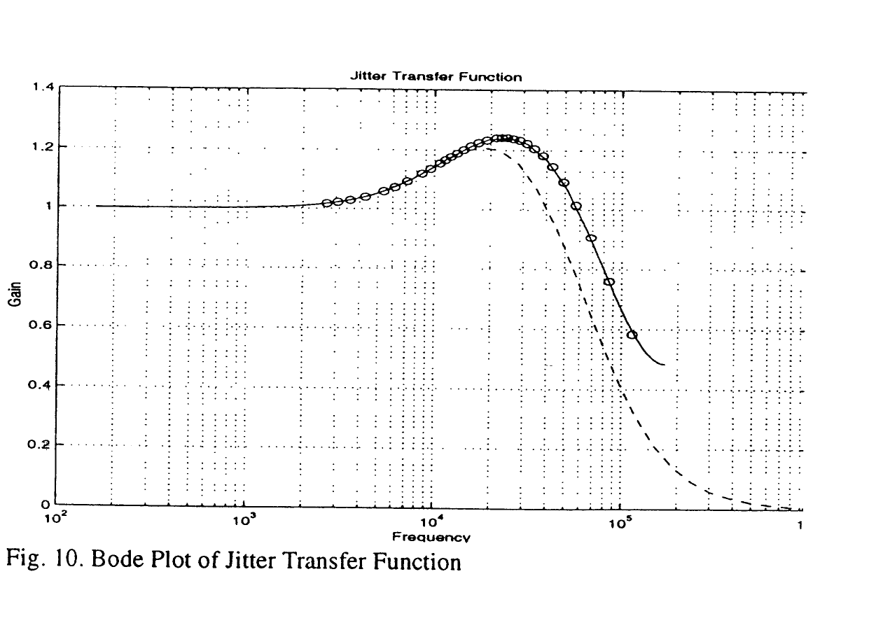

The frequency of the input jitter on the clock is swept and the DFT analysis equation is used to extract the magnitude and phase at each frequency. An S-domain model, a 3rd order Z-transform model (see Additional details below) and this model are compared in FIG. 10.

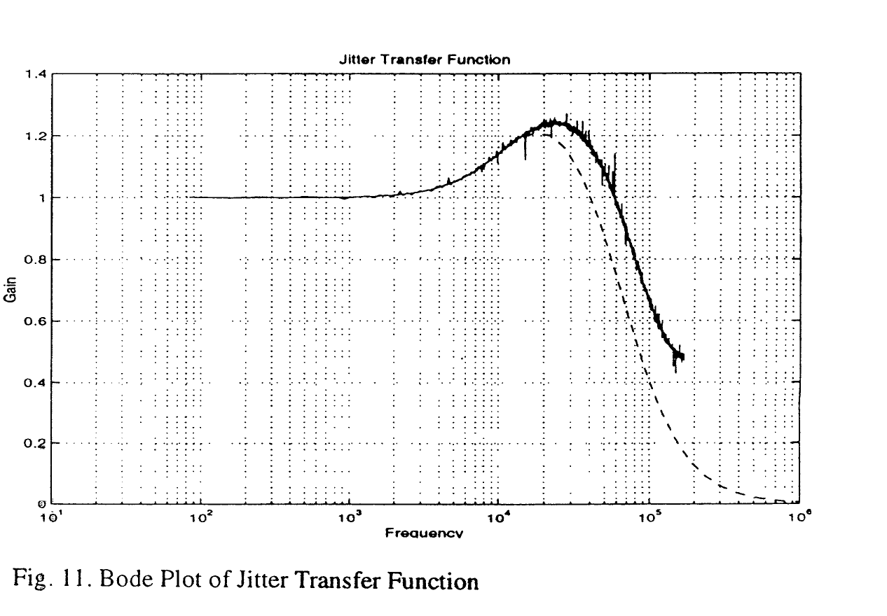

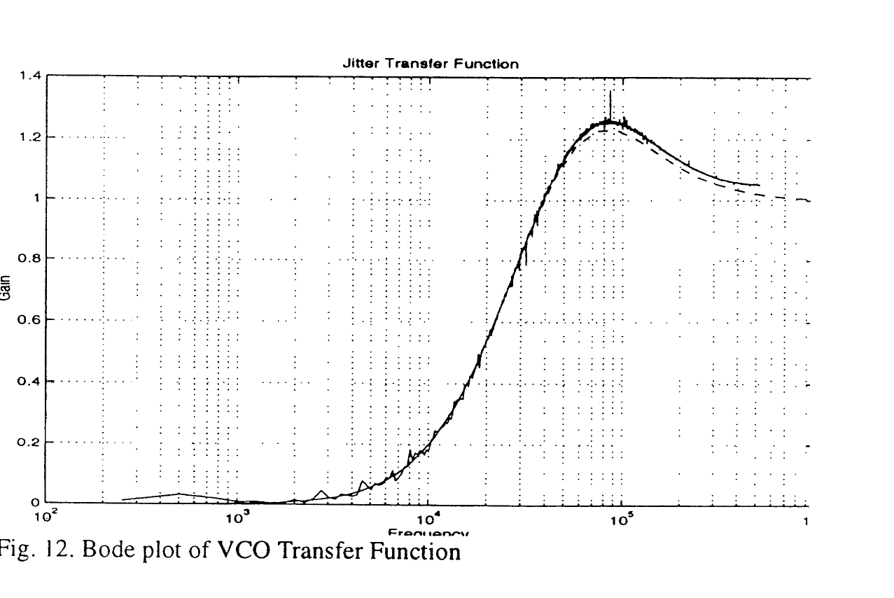

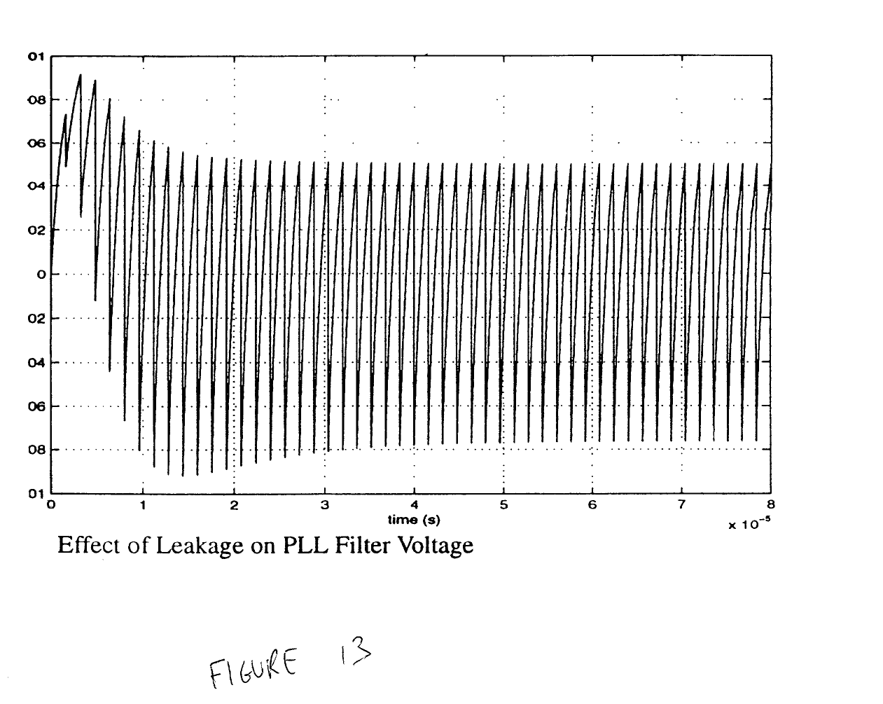

In another embodiment, random jitter is added to the input clock of the PLL. An FFT is performed on the input and output jitter and the two results are divided. The results are shown in FIG. 11.

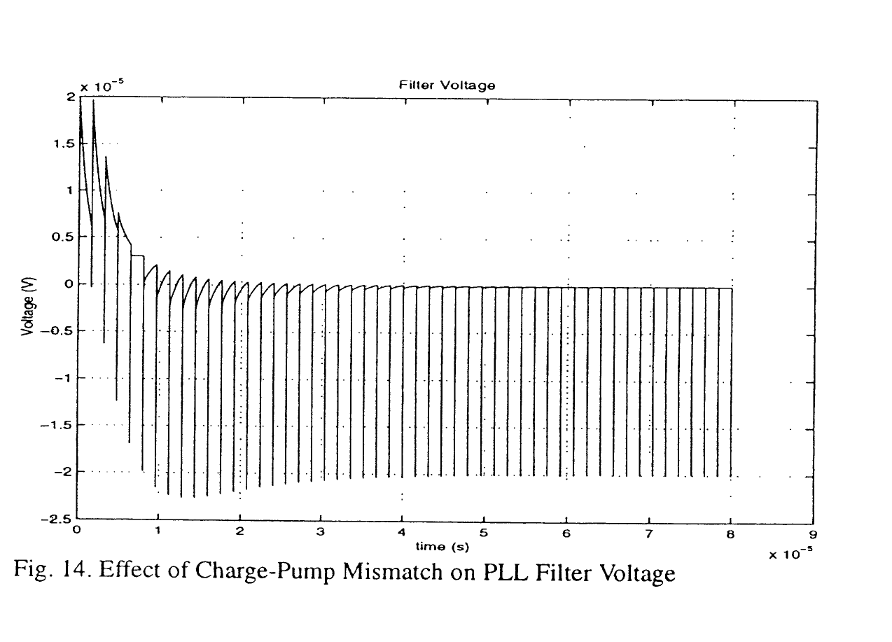

The frequency response of the loop to VCO jitter can also be derived. After each VCO switching point is calculated, random jitter is added to the time-point. The response is derived by dividing the FFT of the output jitter with the VCO jitter as illustrated in FIG. 12.

### Transient Analysis

Filter leakage is a problem if there is some leakage current flowing between PD/CP refresh times. These leakage current will slowly discharge the filter voltage and the VCO frequency will begin to drift between refresh instants (FIG. 13). This can be very troublesome at high divider rates. This effect can be modeled by adding an extra step at time equals zero to the filter voltage equation. The model can also include a divider in the feedback path by quantizing the threshold ‘a’ in equation (4) by the division ratio.

Jitter can be introduced if the CP charging and discharging currents are unequal. The standard sequential PD will have generate both up and down pulses together to avoid dead-zone problems. If the currents are exactly equal the filter is not disturbed. However if the they are unequal, this will introduce jitter on the filter voltage which will modulate the output clock. Extra unit steps can be added to the equations to model this effect. The model can also include a divider in the feedback path to simulate clock multiplication and/or fractional N synthesis.

### 5.0 Additional Details

A 3rd order Z-transform of a CP-PLL may be derived using an impulse invariant transform. The open-loop gain G(z) is given by

$$\begin{matrix}G ( z ) = {K}^{1} \cdot \frac{{z}^{2} \cdot ( T + {c}_{0} ( 1 - {c}_{1} ) ) - z \cdot ( {c}_{1} \cdot T + {c}_{0} \cdot ( 1 - {c}_{1} ) )}{{z}^{3} - {z}^{2} \cdot ( {c}_{1} + 2 ) + z \cdot ( 2 \cdot {c}_{1} + 1 ) - {c}_{1}} \\ where & Eqn . 8 \\ {c}_{0} = \frac{R \cdot {C}^{2}}{{C}_{p} + C} & Eqn . 9 \\ and c1 = exp ( T \cdot \frac{C + {C}_{p}}{R \cdot C \cdot {C}_{p}} ) \\ and & Eqn . 10 \\ {K}^{1} = \frac{K \cdot T}{{C}_{p} + C} & Eqn . 11\end{matrix}$$

The closed loop transfer function H(z) can be found using

$$H ( z ) = \frac{G ( z )}{1 + G ( z )} \qquad Eqn . 12$$

The model may be synthesized as a digital circuit and/or used as an ADPLL (All Digital PLL). It is to be understood that embodiments of this invention may also be used as or to support software programs executed upon some form of processing core (such as the CPU of a computer) or otherwise implemented or realized upon or within a machine readable medium. A machine readable medium includes any mechanism for storing or transmitting information in a form readable by a machine (e.g., a computer). For example, a machine readable medium includes read only memory (ROM); random access memory (RAM); magnetic disk storage media; optical storage media; flash memory devices; electrical, optical, acoustical or other form of propagated signals (e.g., carrier waves, infrared signals, digital signals, etc.); etc.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

What is claimed is:

1. A method, comprising:
representing a charge pump output signal as a superposition of current steps that step in opposite directions at different times.

2. The method of claim 1 further comprising determining a filter output voltage that results from said charge pump output signal by adding current step responses to each of said current steps.

3. The method of claim 1 wherein a first of said current steps occurs when a reference clock edge rises.

4. The method of claim 3 wherein said first current step is in a positive direction.

5. The method of claim 1 wherein a second of said current steps occurs when voltage controlled oscillator output clock edge rises.

6. The method of claim 5 wherein said second current step is in a negative direction.

7. A method, comprising:
a) calculating a filter output voltage by adding a pair of current step responses to a summation of prior pairs of current step responses;
b) calculating an instant of time when an integration of said filter output voltage will reach a reference voltage;
c) triggering a voltage controlled oscillator output clock edge at said instant of time; and
d) stepping a pair of current steps at a temporal offset with respect to one another, said temporal offset equal to a difference between a rising voltage controlled oscillator output clock edge instant of time and a rising reference clock edge instant of time.

8. The method of claim 7 wherein said stepping a pair of current steps further comprises stepping a first current step at said rising reference clock edge instant of time.

9. The method of claim 8 wherein said first current step is positive.

10. The method of claim 8 wherein said stepping a pair of current steps further comprises stepping a second current step at said rising voltage controlled oscillator output clock edge instant of time.

11. The method of claim 10 wherein said second current step is negative.

12. The method of claim 7 further comprising setting said integration of said filter voltage to zero after said reference voltage is reached.

13. The method of claim 7 wherein said calculating corresponds to a recalculation of when said filter voltage will reach said reference voltage, said pair of current step responses produced by a lagging rising voltage controlled oscillator output clock edge.

14. A machine readable medium having stored thereon sequences of instructions which are executable by a digital processing system, and which, when executed by the digital processing system, cause the system to perform a method comprising, comprising:
representing a charge pump output signal as a superposition of current steps that step in opposite directions at different times.

15. The machine readable medium of claim 14 wherein said method further comprises determining a filter output voltage that results from said charge pump output signal by adding current step responses to each of said current steps.

16. The machine readable medium of claim 14 wherein a first of said current steps occurs when a reference clock edge rises.

17. The machine readable medium of claim 16 wherein said first current step is in a positive direction.

18. The machine readable medium of claim 14 wherein a second of said current steps occurs when voltage controlled oscillator output clock edge rises.

19. The machine readable medium of claim 18 wherein said second current step is in a negative direction.

20. A machine readable medium having stored thereon sequences of instructions which are executable by a digital processing system, and which, when executed by the digital processing system, cause the system to perform a method comprising:
a) calculating a filter output voltage by adding a pair of current step responses to a summation of prior pairs of current step responses;
b) calculating an instant of time when an integration of said filter output voltage will reach a reference voltage;
c) triggering a voltage controlled oscillator output clock edge at said instant of time; and
d) stepping a pair of current steps at a temporal offset with respect to one another, said temporal offset equal to a difference between a rising voltage controlled oscillator output clock edge instant of time and a rising reference clock edge instant of time.

21. The machine readable medium of claim 20 wherein said stepping a pair of current steps further comprises stepping a first current step at said rising reference clock edge instant of time.

22. The machine readable medium of claim 21 wherein said first current step is positive.

23. The machine readable medium of claim 21 wherein said stepping a pair of current steps further comprises stepping a second current step at said rising voltage controlled oscillator output clock edge instant of time.

24. The machine readable medium of claim 23 wherein said second current step is negative.

25. The machine readable medium of claim 20 wherein said method further comprises setting said integration of said filter voltage to zero after said reference voltage is reached.

26. The machine readable medium of claim 20 wherein said calculating corresponds to a recalculation of when said filter voltage will reach said reference voltage, said pair of current step responses produced by a lagging rising voltage controlled oscillator output clock edge.
